(19) United States
(12) Patent Application Publication
(10) Pub. No.: US 2006/0238833 A1
(43) Pub. Date: Oct. 26, 2006

(54) Portable information product having a built-in projection device

(76) Inventor: Lu-Cheng Chen, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/242,848

(22) Filed: Oct. 5, 2005

(30) Foreign Application Priority Data
Apr. 22, 2005 (TW) 94112990

(51) Int. Cl. G03F 3/08

(52) U.S. Cl. 358/520

(57) ABSTRACT

A portable information product having a built-in projection device, such as a cellular phone, a portable computer, a personal digital assistant, or various types of portable information products, has a data processing device and a built-in projection device. The data processing device has a main circuit module for processing data thereof and forming an output signal from the data. The built-in projection device is disposed in the data processing device and electrically connects to the main circuit module. The projection device has a light source and a projector. The light source generates a light. The light and the output signal are transmitted to the projector to form an image, and the projector projects the image outside the data processing device. As a result, the data of the data processing device is easier to view.

### BACKGROUND OF THE INVENTION

1. Field of the Invention

The present invention relates to a portable information product, and more particularly, to a portable information product having a built-in projection device.

2. Background of the Invention

Portable information products are becoming more and more popular. For example, cellular phones, portable computers, and personal digital assistants are all small in size and have a variety of functions. It is easy for users to take portable information products with them to help them organize their daily affairs or offer a source of entertainment at any time.

A conventional portable information product displays data thereof on a display device thereof.

The display device of the conventional portable information product has a limited size and is only designed for a single user to view. As such, it is difficult for others to view the display at the same time. It lacks practicality if a user wants to show information stored on the portable information product to others, if, as an example, they are in a conference with several people.

Accordingly, as discussed above, the conventional portable information product still has some drawbacks that could be improved upon. The present invention aims to resolve the drawbacks in the prior art.

### SUMMARY OF INVENTION

The primary objective of the invention is therefore to specify a portable information product having a built-in projection device, wherein a built-in projection device is disposed in a data processing device, and the projection device outputs an output signal formed by the data processing device and outside the data processing device, so that others can view the data of the data processing device more easily.

According to the invention, the objective is achieved via a portable information product having a built-in projection device. The portable information product comprises a data processing device and a built-in projection device. The data processing device has a main circuit module for processing data thereof and forming an output signal from the data. The built-in projection device is disposed in the data processing device and electrically connects to the main circuit module. The projection device has a light source and a projector. The light source generates a light. The light and the output signal are transmitted to the projector to form an image, and the projector projects the image outside the data processing device.

The built-in projection device is disposed in the data processing device. As such, that the output signal formed by the data processing device is outputted via the projection device and others can view the data of the data processing device more easily.

To provide a further understanding of the invention, the following detailed description illustrates embodiments and examples of the invention. Examples of the more important features of the invention thus have been summarized rather broadly in order that the detailed description thereof that follows may be better understood, and in order that the contributions to the art may be appreciated. There are, of course, additional features of the invention which will be described hereinafter and which will form the subject of the claims appended hereto.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic block diagram of a first embodiment of an interior system according to a portable information product having the built-in projection device of the present invention;

FIG. 2 is a schematic block diagram of a second embodiment of an interior system according to a portable information product having the built-in projection device of the present invention;

FIG. 3 is a perspective view of a first embodiment according to a portable information product having the built-in projection device of the present invention;

FIG. 4 is a perspective view of a second embodiment according to a portable information product having the built-in projection device of the present invention;

FIG. 5 is a perspective view of a third embodiment according to a portable information product having the built-in projection device of the present invention; and

FIG. 6 is a perspective view of a fourth embodiment according to a portable information product having the built-in projection device of the present invention.

### DETAILED DESCRIPTION OF THE EMBODIMENTS

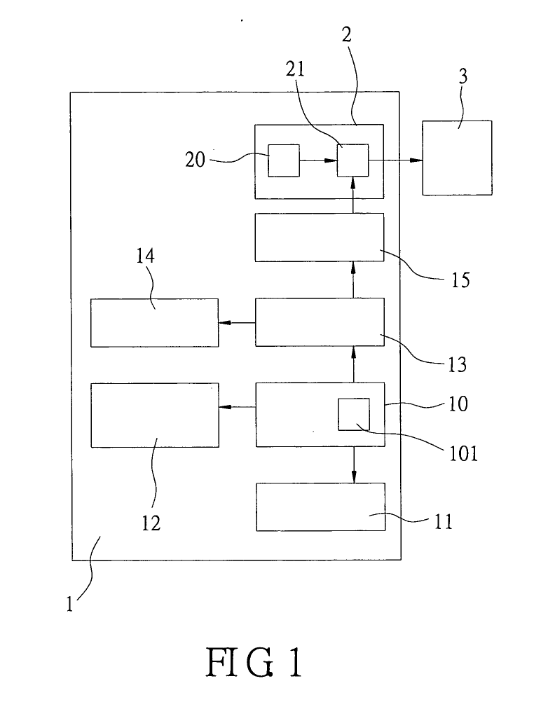

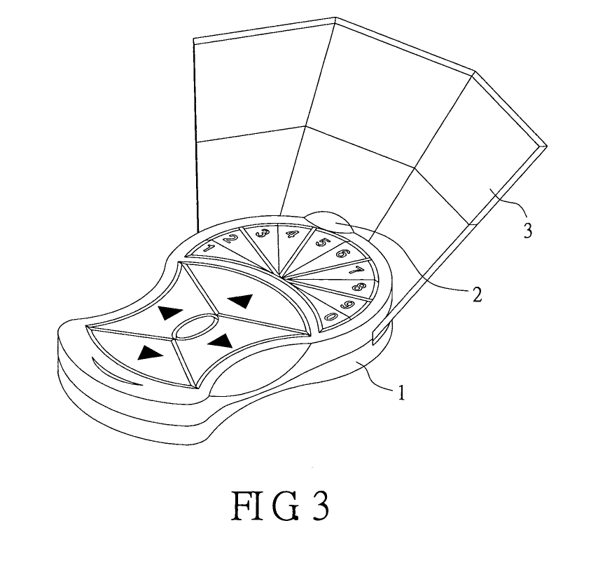

The present invention provides a portable information product having a built-in projection device. FIG. 1 shows a first embodiment of an interior system according to a portable information product having a built-in projection device of the present invention. As shown in FIGS. 3-6, the portable information product may be a cellular phone, a portable computer, a personal digital assistant, or any type of portable information product. The portable information product comprises a data processing device 1 and a built-in projection device 2.

The data processing device 1 has a main circuit module 10. The main circuit module 10 has a microprocessor 101, various essential program processors (not shown), various essential memories (not shown), and other electronic elements, for processing data thereof and forming an output signal from the data.

The data processing device 1 has a storage device 11 and an application circuit module 12. The storage device 11 may be a hard disk driver, a card reader, or any type of device that provides storage functions. The storage device 11 electrically connects to the main circuit module 10 for storing data of the data processing device 1. The application circuit module 12 may be a charging circuit module, an audio circuit module, or any type of functional application circuit module. The application circuit module 12 electrically connects to the main circuit module 10 for processing data stored on the data processing device 1.

The built-in projection device 2 is disposed in the data processing device 1 and electrically connects to the main circuit module 10. The projection device 2 has a light source 20 and a projector 21. The light source 20 may be a light emitting diode (LED) for generating light. The projector 21 may be an image forming structure composed of optical elements and electronic elements.

As shown in FIG. 1, the data processing device 1 also has a switching circuit module 13, a display device 14, and a projection and amplifying circuit module 15. The switching circuit module 13 electrically connects between the main circuit module 10 and the projection device 2, and between the main circuit module 10 and the display device 14. The display device 14 may be a liquid crystal display (LCD). The projection and amplifying circuit module 15 electrically connects between the main circuit module 10 and the projector 21 of the projection device 2, and is between the switching circuit module 13 and the projector 21, for processing and amplifying output signals from the main circuit module 10.

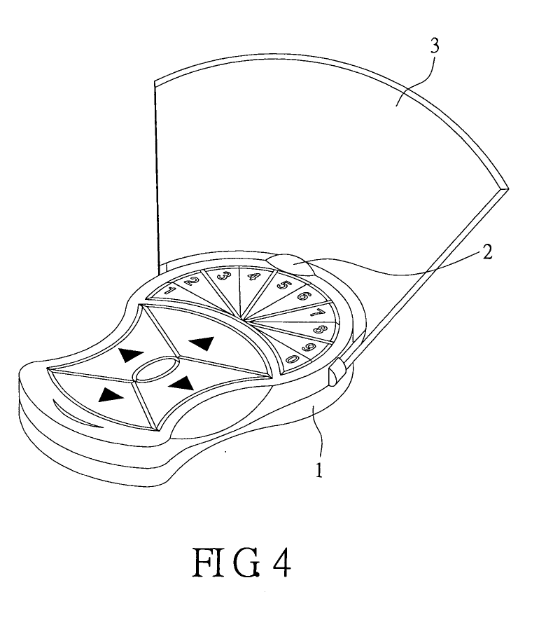

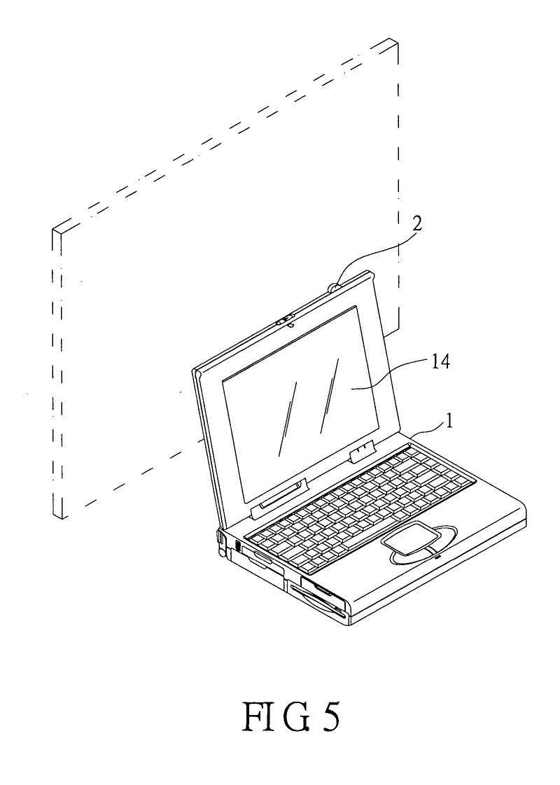

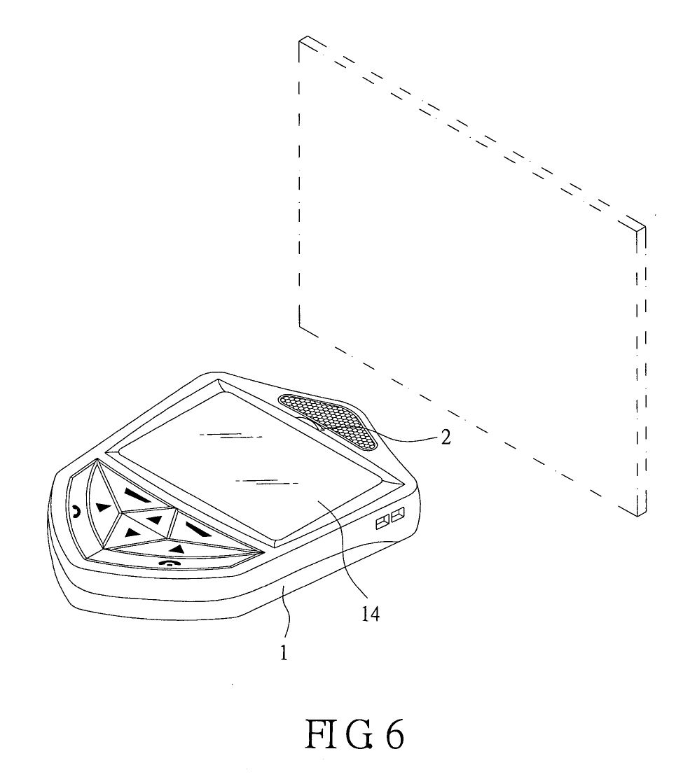

The portable information product having a built-in projection device of the present invention uses the projection device 2 and/or the display device 14 to display the output signal formed from the data thereof. The output signal is alternatively transmitted to the projection device 2 and/or the display device 14 through the switching circuit module 13. The portable information product may further comprise a screen 3 for projection. As shown in FIG. 3, the screen 3 retrievably connects to the data processing device 1. As shown in FIG. 4, the screen 3 detachably assembles to the data processing device 1. When a user uses the projection device 2 to display the data of the data processing device 1, the output signal is transmitted to the projector 21 via the projection and amplifying circuit module 15, and the light source 20 generates a light. The light and the output signal are transmitted to the projector 21 to form an image, and the projector 21 projects the image onto the screen 3 outside the data processing device 1. As a result, more people can view the image simultaneously. As shown in FIG. 5 and FIG. 6, the portable information product may also not have a screen for projection. In this case, the projector 21 directly projects the image onto an appropriate surface outside the data processing device 1. The user may also use the display device 14 to display data stored on the data processing device 1, or use the projection device 2 and the display device 14 to display data stored on the data processing device 1 simultaneously.

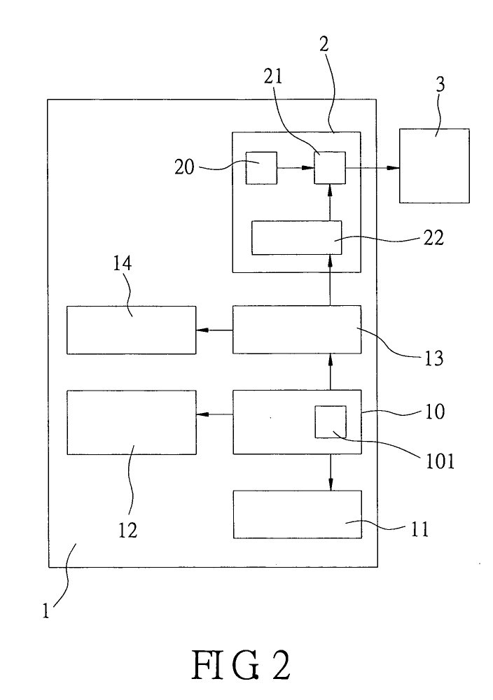

FIG. 2 shows a second embodiment of an interior system according to a portable information product having a built-in projection device of the present invention. The difference between FIG. 2 and FIG. 1 is the projection and amplifying circuit module 22. In FIG. 2, the projection device 2 has a projection and amplifying circuit module 22 electrically connecting between the main circuit module 10 and the projector 21 of the projection device 2, and is between the switching circuit module 13 and the projector 21. The output signal is transmitted to the projector 21 via the projection and amplifying circuit module 22. Therefore, the projection and amplifying circuit module may be integrated with the projection device or the data processing device.

As indicated above, the portable information product having a built-in projection device of the present invention has the following advantages:

(1) The built-in projection device is disposed in the data processing device, so that the output signal formed by the data processing device is outputted via the built-in projection device, so that data stored on the data processing device is easier to view.

(2) The screen retrievably connects to the data processing device, or the screen detachably assembles onto the data processing device, or the portable information product may not have a screen, so that the portable information product is more convenient.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A portable information product having a built-in projection device comprising:
a data processing device having a main circuit module for processing data thereof and forming an output signal from the data; and
a built-in projection device disposed in the data processing device and electrically connecting to the main circuit module, the projection device having a light source and a projector, the light source generating a light, the light and the output signal being transmitted to the projector to form an image, and the projector projecting the image outside the data processing device.

2. The portable information product as claimed in claim 1, wherein the portable information product is a cellular phone.

3. The portable information product as claimed in claim 1, wherein the portable information product is a portable computer.

4. The portable information product as claimed in claim 1, wherein the portable information product is a personal digital assistant.

5. The portable information product as claimed in claim 1, wherein the main circuit module of the data processing device has a microprocessor for processing the data of the data processing device.

6. The portable information product as claimed in claim 1, wherein the data processing device has a storage device electrically connecting to the main circuit module for storing data of the data processing device.

7. The portable information product as claimed in claim 1, wherein the data processing device has an application circuit module electrically connecting to the main circuit module for processing data of the data processing device.

8. The portable information product as claimed in claim 1, wherein the data processing device has a switching circuit module and a display device, the switching circuit module electrically connects between the main circuit module and the projection device, and between the main circuit module and the display device, and the output signal is alternatively transmitted to the projection device and/or the display device through the switching circuit module.

9. The portable information product as claimed in claim 1, wherein the data processing device has a projection and amplifying circuit module electrically connecting between the main circuit module and the projector of the projection device, and the output signal is transmitted to the projector via the projection and amplifying circuit module.

10. The portable information product as claimed in claim 1, wherein the projection device has a projection and amplifying circuit module electrically connecting between the main circuit module and the projector of the projection device, and the output signal is transmitted to the projector via the projection and amplifying circuit module.

11. The portable information product as claimed in claim 1, comprising a screen for projection, and the screen retrievably connects to the data processing device.

12. The portable information product as claimed in claim 1, comprising a screen for projection, and the screen detachably assembles to the data processing device.
